(19) United States
(12) Patent Application Publication
(10) Pub. No.: US 2025/0130139 A1
(43) Pub. Date: Apr. 24, 2025

(54) DEVICE OF TESTING RELIABILITY OF DISPLAY PANEL AND METHOD OF TESTING RELIABILITY OF DISPLAY PANEL USING THE SAME

(71) Applicant: Samsung Display Co., LTD., Yongin-si (KR)

(72) Inventors: SUNG-HWAN HONG, Yongin-si (KR); BYUNG GOO JUNG, Yongin-si (KR); YUNHEE KWAK, Yongin-si (KR); YOUNGJEON KIM, Yongin-si (KR); HYUNG KEON CHO, Yongin-si (KR); JAEWON CHOI, Yongin-si (KR)

(21) Appl. No.: 18/825,246

(22) Filed: Sep. 5, 2024

(30) Foreign Application Priority Data
Oct. 20, 2023 (KR) 10-2023-0141335

(51) Int. Cl. G01M 99/00

(52) U.S. Cl. CPC G01M 99/005

(57) ABSTRACT

A display panel reliability test device includes a heating plate, a jig disposed on the heating plate and including a water tank and a supporter surrounding the water tank, and a packing cover disposed on the jig and overlapping the water tank in a plan view. A test space defined as a space surrounded by the jig and the packing cover and accommodating a test-purpose display panel therein is maintained at a temperature equal to or greater than about 80 degrees Celsius and equal to or smaller than about 90 degrees Celsius and a relative humidity equal to or greater than about 95% and equal to or smaller than about 100% for about 300 hours or more.

This application claims priority to Korean Patent Application No. 10-2023-0141335, filed on Oct. 20, 2023, and all the benefits accruing therefrom under 35 U.S.C. § 119, the content of which in its entirety is herein incorporated by reference.

### BACKGROUND

### 1. Field

The disclosure relates to a device of testing a reliability of a display panel and a method of testing the reliability of the display panel using the same. More particularly, the disclosure relates to a device of testing a reliability of a display panel, which improves the efficiency and convenience in evaluating the reliability of the display panel, and a method of testing the reliability of the display panel using the test device.

### 2. Description of Related Art

Various display devices used in multimedia devices, such as televisions, mobile phones, tablet computers, navigation devices, and game devices, are being developed. Display panels included in the display devices are corroded when being exposed to high temperature or high humidity for a long period of time, and performance of the display panels is deteriorated. It is desired to expose the display panel to a high temperature and humidity environment for a certain period of time to test the reliability of the display panel included in the display device.

Various approaches are being attempted to improve the convenience and efficiency in testing the reliability of the display panel.

### SUMMARY

The disclosure provides a device of testing a reliability of a display panel, which is capable of providing a reliable test environment where the display panel is disposed in a space with a relatively high temperature and humidity environment achieved by heating water in a water tank and sealed with a packing cover.

The disclosure provides a method of testing the reliability of the display panel, which is carried out in a reliable test environment where the display panel is disposed in a space with a relatively high temperature and humidity environment achieved by heating water in a water tank and sealed with a packing cover.

An embodiment of the inventive concept provides a device of testing a reliability of a display panel including a heating plate, a jig disposed on the heating plate and including a water tank and a supporter surrounding the water tank, and a packing cover disposed on the jig and overlapping the water tank in a plan view. A test space defined as a space surrounded by the jig and the packing cover and accommodating a test-purpose display panel therein is maintained at a temperature equal to or greater than about 80 degrees Celsius and equal to or smaller than about 90 degrees Celsius and a relative humidity equal to or greater than about 95% and equal to or smaller than about 100% for about 300 hours or more.

In an embodiment, the water tank includes a plurality of unit water tanks, the supporter includes a plurality of unit supporters respectively surrounding the plurality of unit water tanks, and the packing cover includes a plurality of unit packing covers respectively overlapping the plurality of unit water tanks in the plan view.

In an embodiment, the jig further includes a waterway connecting at least some of the plurality of unit water tanks to each other.

In an embodiment, the water tank includes a plurality of water tanks, and the packing cover overlaps the plurality of unit water tanks in the plan view.

In an embodiment, the jig is disposed directly on the heating plate.

In an embodiment, the packing cover is disposed directly on the jig.

In an embodiment, the heating plate includes a thermally conductive material.

In an embodiment, the thermally conductive material includes at least one of Fe, Cu, Ag, Au, Al, and W.

In an embodiment, the supporter includes a thermally conductive material.

In an embodiment, the thermally conductive material includes at least one of Fe, Cu, Ag, Au, Al, and W.

In an embodiment, the device further includes a first supporter disposed on the supporter, and the test-purpose display panel is placed on the first supporter.

In an embodiment, the device further includes a second supporter disposed on the supporter and preventing the test-purpose display panel from moving in a first direction or a direction opposite to the first direction.

In an embodiment, a fixing groove is defined in the supporter, and a portion of the packing cover is disposed in the fixing groove.

In an embodiment, the fixing groove surrounds the water tank in the plan view.

In an embodiment, the packing cover has a quadrangular shape in the plan view.

An embodiment of the inventive concept provides a method of testing a reliability of a display panel. The method includes providing a heating plate and a jig disposed on the heating plate and including a water tank and a supporter surrounding the water tank, providing a predetermined water to the water tank, placing a test-purpose display panel to overlap the water tank in a plan view, placing a packing cover to cover at least a portion of the test-purpose display panel, applying a heat to the heating plate to maintain a test space defined as a space surrounded by the jig and the packing cover at a temperature equal to or greater than about 80 degrees Celsius and equal to or smaller than about 90 degrees Celsius and a relative humidity equal to or greater than about 95% and equal to or smaller than about 100%, and identifying whether the test-purpose display panel is corroded.

In an embodiment, the water tank includes a plurality of unit water tanks, the supporter includes a plurality of unit supporters respectively surrounding the plurality of unit water tanks, the packing cover includes a plurality of unit packing covers respectively overlapping the plurality of unit water tanks in the plan view, the providing the water includes providing water to each of the plurality of unit water tanks, the placing the test-purpose display panel includes placing a plurality of test-purpose display panels to respectively overlap the plurality of unit water tanks, and the placing the packing cover includes placing the unit packing covers to respectively cover the test-purpose display panels.

In an embodiment, the jig further includes a waterway connecting at least some of the plurality of unit water tanks to each other.

In an embodiment, the placing the test-purpose display panel is performed to place the test-purpose display panel on a first supporter disposed on the supporter, and the test-purpose display panel placed on the first supporter overlaps the water tank in the plan view.

In an embodiment, the applying the heat to the heating plate is performed to maintain the test space at the temperature equal to or greater than about 80 degrees Celsius and equal to or smaller than about 90 degrees Celsius and the relative humidity equal to or greater than about 95% and equal to or smaller than about 100% for about 300 hours or more.

According to the above, the device of testing the reliability of the display panel allows the temperature and humidity to be controlled easily by heating water in a sealed test space and reduces the time it takes for the display panel to corrode, and thus, the convenience and efficiency in testing the reliability of the display panel are improved.

According to the above, the method of testing the reliability of the display panel provides improved convenience and efficiency in testing the reliability of the display panel by allowing the temperature and humidity to be controlled easily by heating water in a sealed test apace and reducing the time it takes for the display panel to corrode.

### BRIEF DESCRIPTION OF THE DRAWINGS

The above and other advantages of the disclosure will become readily apparent by reference to the following detailed description when considered in conjunction with the accompanying drawings, in which:

FIG. 1 is a perspective view of an embodiment of a device of testing a reliability of a display panel according to the disclosure;

FIG. 2 is a perspective view of an embodiment of a device of testing a reliability of a display panel according to the disclosure;

FIG. 3A is an exploded perspective view of the device of testing the reliability of the display panel of FIG. 1;

FIG. 3B is an exploded perspective view of the device of testing the reliability of the display panel of FIG. 2;

FIG. 4 is a perspective view of an embodiment of a portion of a device of testing a reliability of a display panel according to the disclosure;

FIG. 5 is a perspective view of an embodiment of a portion of a device of testing a reliability of a display panel according to the disclosure;

FIGS. 6 and 7 are cross-sectional views taken along line I-I′ of FIG. 1;

FIG. 8 is a flowchart illustrating an embodiment of a method of testing a reliability of a display panel according to the disclosure;

FIG. 9 is a perspective view illustrating an embodiment of a process of a method of testing a reliability of a display panel according to the disclosure;

FIG. 10 is a perspective view illustrating an embodiment of a process of a method of testing a reliability of a display panel according to the disclosure;

FIG. 11A is a perspective view illustrating an embodiment of a process of a method of testing a reliability of a display panel according to the disclosure;

FIG. 11B is a plan view of a test-purpose display panel shown in FIG. 11A;

FIG. 12 shows graphs illustrating a moisture concentration as a function of time in Experimental embodiment and Comparative example 1; and

FIG. 13 shows graphs illustrating a moisture concentration as a function of time in Comparative examples 1 and 2.

### DETAILED DESCRIPTION

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the drawing figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the disclosure, when an element is referred to as being “directly connected” to another element, there are no intervening elements between a layer, film region, or substrate and another layer, film, region, or substrate. For example, the term “directly connected” may mean that two layers or two members are disposed without employing additional adhesive therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the disclosure, a third direction DR3 is defined as a thickness direction. A first direction DR1 intersects the third direction DR3, and a second direction DR2 intersects the first direction DR1.

In the disclosure, the expression “in a plan view” may mean a state of being viewed in the plan view defined by the first and second directions DR1 and DR2.

Hereinafter, a device TD of testing a reliability of a display panel (hereinafter, also referred to as a “display panel reliability test device”) and a method of testing the reliability of the display panel will be described with reference to accompanying drawings.

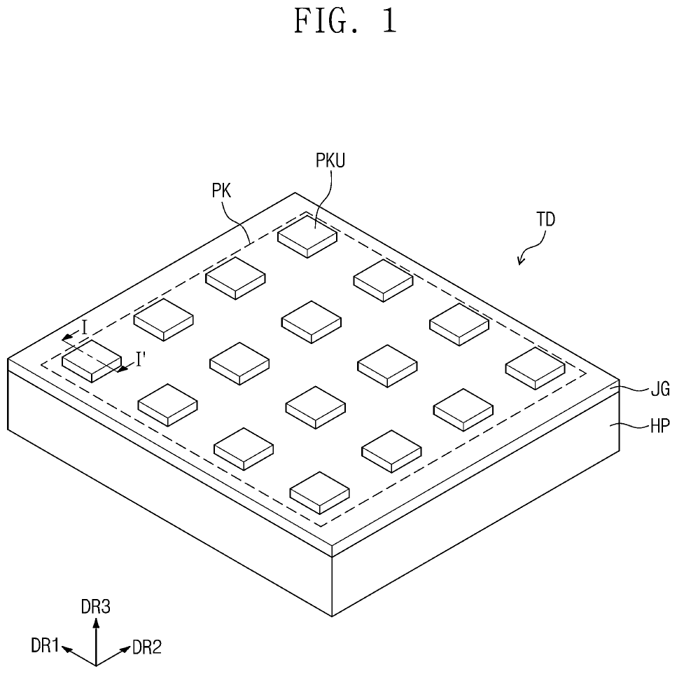

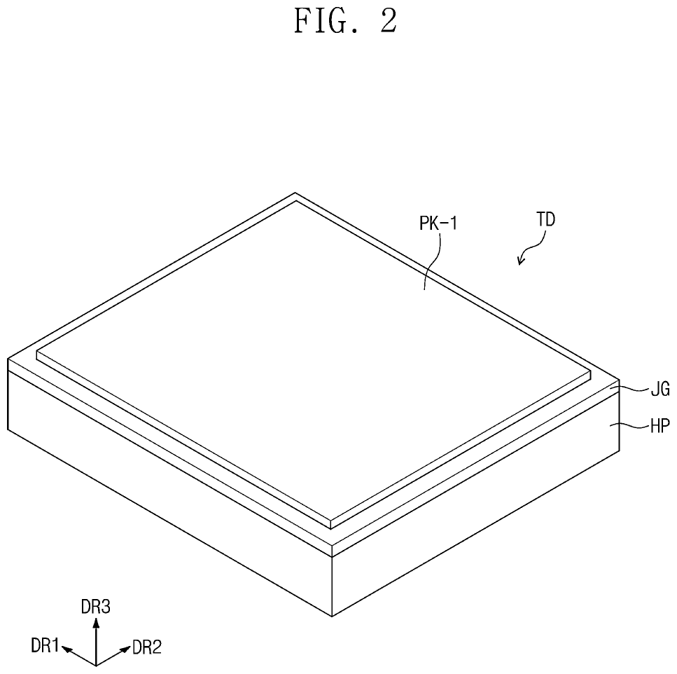

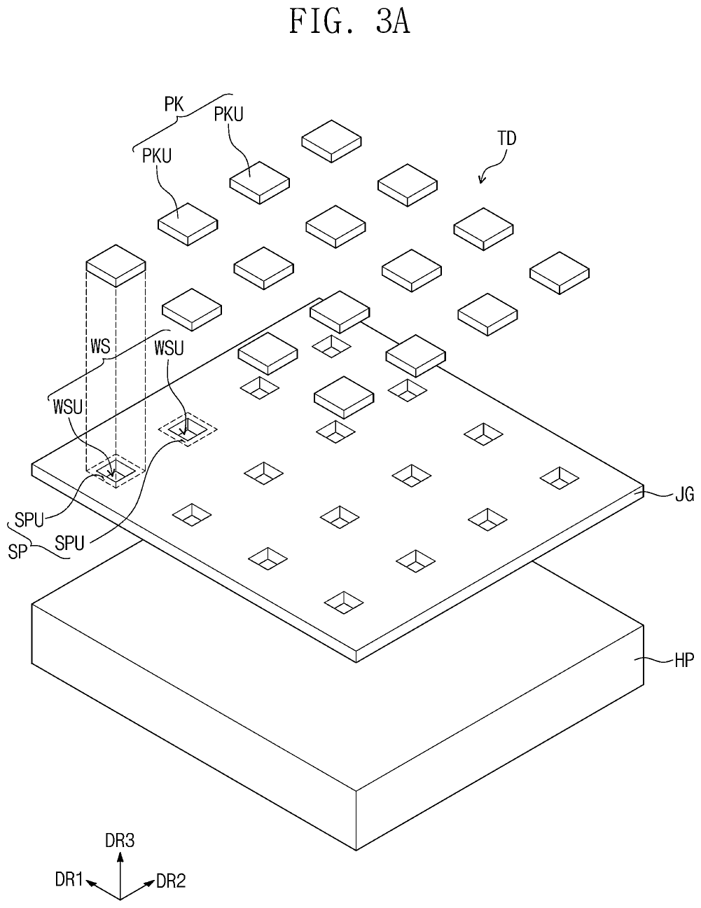

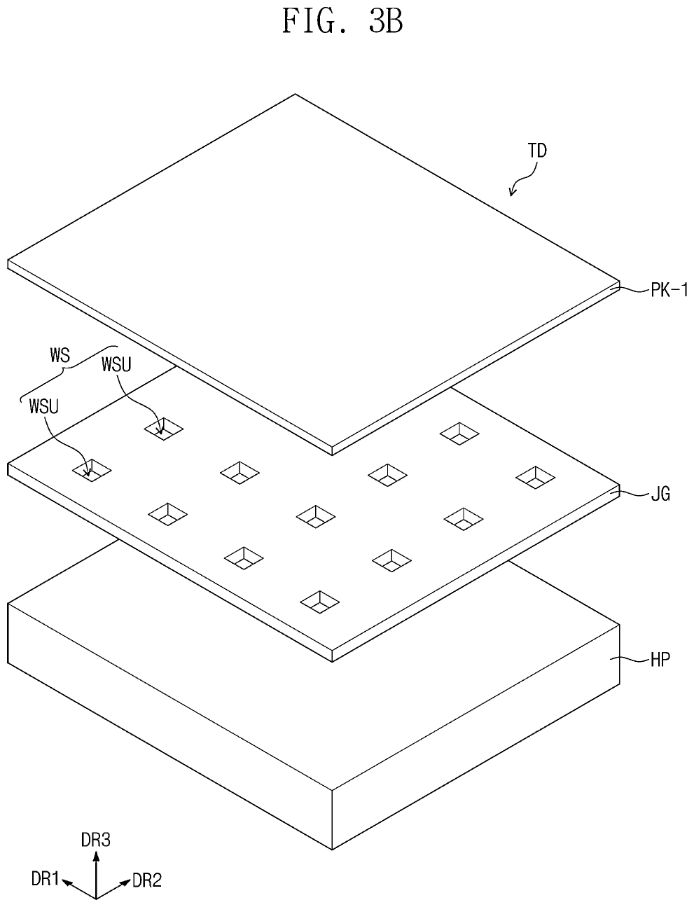

FIG. 1 is a perspective view of an embodiment of the display panel reliability test device TD according to the disclosure. FIG. 2 is a perspective view of an embodiment of the display panel reliability test device TD according to the disclosure. FIG. 3A is an exploded perspective view of the display panel reliability test device TD of FIG. 1. FIG. 3B is an exploded perspective view of the display panel reliability test device TD of FIG. 2.

Referring to FIGS. 1 and 3A, the display panel reliability test device TD may include a heating plate HP, a jig JG, and a packing cover PK.

The display panel reliability test device TD may be a device to evaluate the reliability of the display panel, and how much time it takes for corrosion to occur on the display panel may be measured after the display panel is exposed to a relatively high temperature and humidity environment. Since the display panel may be exposed to the relatively high temperature and humidity environment during a distribution and storage process, the method of testing the reliability of the display panel through the display panel reliability test device TD may contribute to creating standards for the distribution and storage process of the display panel.

The heating plate HP may radiate heat in the third direction DR3. The heating plate HP may radiate the heat through an electromagnetic induction heating manner that radiates the heat through a magnetic field generated when a current flows through an electromagnetic induction coil. The heating plate HP may include a thermally conductive material. The thermally conductive material may include or consist of at least one of Fe, Cu, Ag, Au, Al, and W.

The jig JG may be disposed on the heating plate HP. The jig JG may be disposed directly on the heating plate HP. The jig JG may include a water tank WS and a supporter SP. The supporter SP may accept the heat generated by the heating plate HP and may radiate the heat. The water tank WS may be a space surrounded by the supporter SP. The water tank WS may be a space including or consisting of water. The water tank WS may include a plurality of unit water tanks WSU. The supporter SP may include a plurality of unit supporters SPU. The unit water tanks WSU may be surrounded by the unit supporters SPU, respectively. Each of the unit water tanks WSU may have a triangular shape, a quadrangular shape, or a circular shape in a plan view. A portion of the water contained in the unit water tank WSU may be directly in contact with the heating plate HP. An upper surface and a lower surface of each of the unit water tanks WSU may have substantially the same size or different sizes from each other.

A temperature of the water contained in each of the unit water tanks WSU may increase by the heat radiated from the heating plate HP. The unit supporter SPU may surround the unit water tank WSU, may accept the heat radiated from the heating plate HP, and may radiate the heat to the unit water tank WSU. The supporter SP may include a thermally conductive material. The thermally conductive material may include at least one of Fe, Cu, Ag, Au, Al, and W. The supporter SP and the heating plate HP may include different materials from each other. In an embodiment, the supporter SP may include Fe, and the heating plate HP may include Cu.

The packing cover PK may be disposed on the jig JG and may overlap the water tank WS in the plan view. The packing cover PK may include a plurality of unit packing covers PKU. The unit packing cover PKU may have a shape that is similar in shape to the unit water tank WSU and is different in size from the unit water tank WSU in the plan view. The unit packing cover PKU may have a quadrangular shape in the plan view. The unit packing cover PKU may have a size greater than a size of the unit water tank WSU in the plan view. The packing cover PK may include an insulation material.

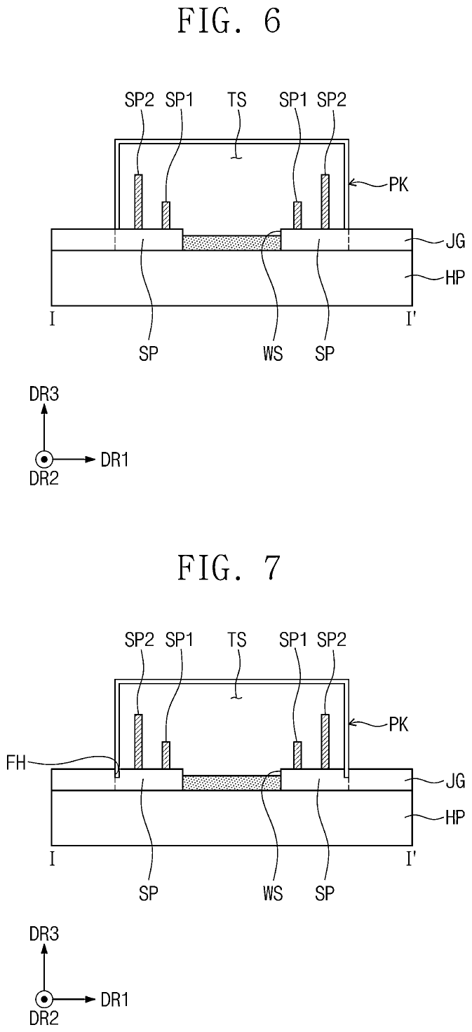

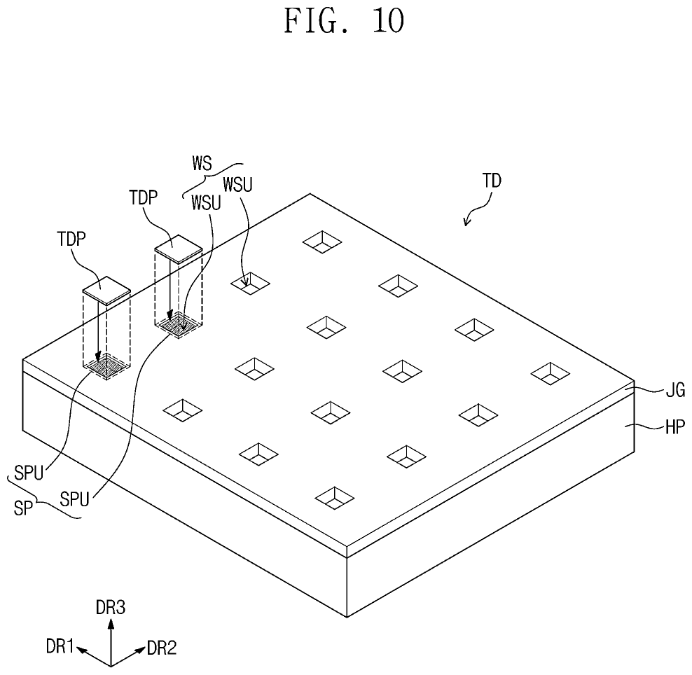

In the display panel reliability test device TD, a space surrounded by the jig JG and the packing cover PK, in which a test-purpose display panel TDP (refer to FIG. 10) is disposed, may be defined as a test space TS (refer to FIG. 6). The heat generated by the heating plate HP may be transferred to the water tank WS and the supporter SP surrounding the water tank WS, which are included in the jig JG. The temperature of the water contained in the water tank WS may increase by the heat radiated from the heating plate HP and the supporter SP. A portion of the water contained in the water tank WS may be changed to water vapor by the heat. A temperature of the test space may be equal to or greater than about 80 degrees Celsius and equal to or smaller than about 90 degrees Celsius, and a relative humidity may be maintained within a range equal to or greater than about 95% and equal to or smaller than about 100% for about 300 hours or more. The test-purpose display panel TDP (refer to FIG. 10) disposed in the test space may be corroded in relatively high temperature and humidity environment with a temperature equal to or greater than about 80 degrees Celsius and equal to or smaller than about 90 degrees Celsius and a relative humidity equal to or greater than about 95% and equal to or smaller than about 100%. As the relative humidity increases, the test-purpose display panel TDP (refer to FIG. 10) is likely to be corroded.

The packing cover PK may be disposed directly on the jig JG. The packing cover PK may be disposed directly on the supporter SP. The unit packing cover PKU may be disposed directly on the unit supporter SPU. Different from the display panel reliability test device TD shown in FIG. 1, a slot-shaped groove may be defined in a side of the packing cover PK. The slot-shaped groove defined in the side of the packing cover PK may have substantially the same thickness as that of the test-purpose display panel TDP (refer to FIG. 10). A portion of the test-purpose display panel TDP (refer to FIG. 10) may be disposed in the test space, and the other portion of the test-purpose display panel TDP (refer to FIG. 10) may be disposed outside the test space through the groove defined in the side of the packing cover PK.

The water tank WS may include the unit water tanks WSU. The supporter SP may include the unit supporters SPU respectively surrounding the unit water tanks WSU. The packing cover PK may include the unit packing covers PKU overlapping the unit water tanks WSU, respectively, in the plan view. The spaces surrounding by the jig JG and the unit packing covers PKU may be defined as the test spaces TS, respectively, and the plural test-purpose display panels TDP (refer to FIG. 10) may be respectively disposed in the test spaces TS (refer to FIG. 6) to be substantially simultaneously subjected to the reliability test. When the test-purpose display panels TDP (refer to FIG. 10) are substantially simultaneously subjected to the reliability test, the accuracy of the reliability test may be improved since there are many examples, and the efficiency of the reliability test may be improved since the reliability of more display panels may be tested at the same period of time.

Referring to FIGS. 2 and 3B, a packing cover PK-1 may overlap a plurality of unit water tanks WSU in the plan view. When the packing cover PK-1 overlaps the unit water tanks WSU in the plan view, it is not desired to place the plural unit packing covers PKU (refer to FIG. 1) to respectively overlap the plural unit water tanks WSU in the plan view to define the test space TS (refer to FIG. 6) since one packing cover PK-1 covers an entirety of the plural unit water tanks WSU in the plan view. Thus, a manufacturing process of the display panel reliability test device may be improved. Even though FIG. 1 shows the sixteen unit water tanks WSU, the disclosure is not limited thereto, and the display panel reliability test device TD may include a different number of the unit water tanks WSU.

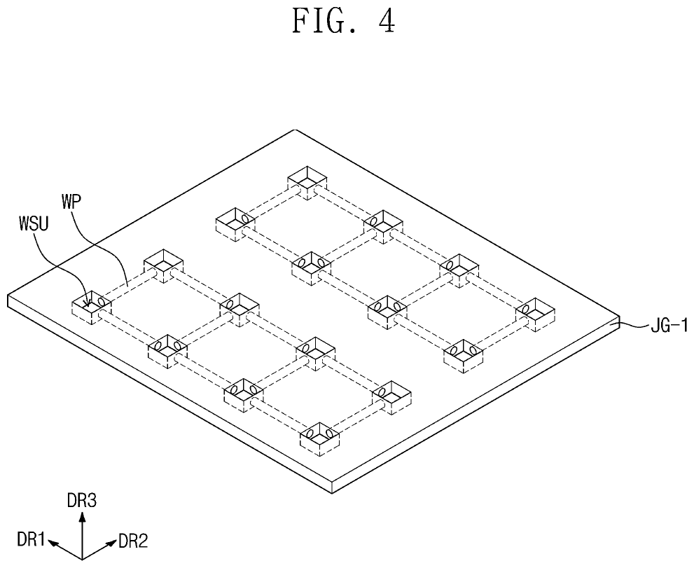

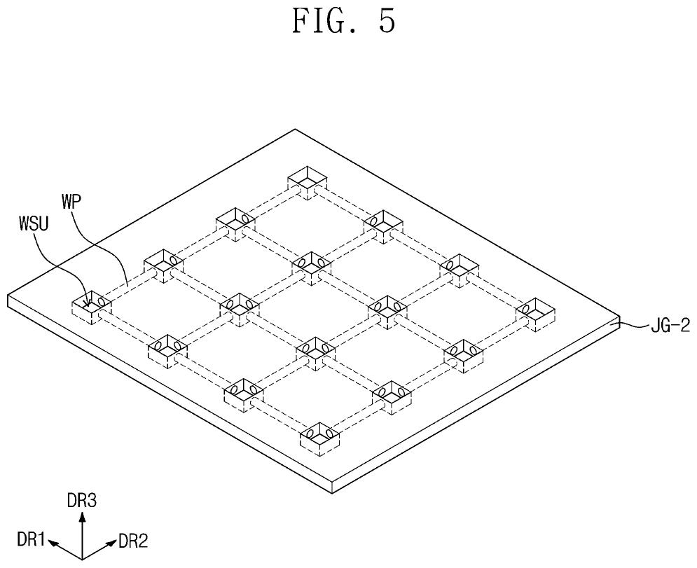

FIG. 4 is a perspective view of an embodiment of a portion of a display panel reliability test device according to the disclosure. FIG. 5 is a perspective view of an embodiment of a portion of a display panel reliability test device according to the disclosure.

FIGS. 4 and 5 show jigs JG-1 and JG-2 included in the display panel reliability test device TD (refer to FIG. 1), respectively. When compared with the jig JG shown in FIG. 3, the jigs JG-1 and JG-2 shown in FIGS. 4 and 5 may further include a waterway WP. The difference between the jig JG-1 shown in FIG. 4 and the jig JG-2 shown in FIG. 5 is that some of unit water tanks WSU are not connected to unit water tanks WSU adjacent thereto through the waterway WP in FIG. 4, but all unit water tanks WSU are connected to unit water tanks WSU adjacent thereto through the waterway WP in FIG. 5.

Referring to FIGS. 4 and 5, the waterway WP included in the jigs JG-1 and JG-2 may connect one unit water tank WSU and another unit water tank WSU adjacent to the one unit water tank WSU to allow water to flow. The waterway WP may connect some of the unit water tanks WSU to each other or may connect all the unit water tanks WSU to each other. In an embodiment, the jig JG-1 shown in FIG. 4 may include one waterway WP that connects eight unit water tanks WSU to each other and the other waterway WP that connects the other eight unit water tanks WSU to each other. The jig JG-2 shown in FIG. 5 may include one waterway WP that connects sixteen unit water tanks WSU to each other. When the water is provided to one unit water tank WSU to which the waterway WP is connected among the unit water tanks WSU, the water may be provided to a unit water tank WSU adjacent thereto and connected to the waterway WP after flowing through the waterway WP. As the jigs JG-1 and JG-2 further include the waterway WP, the water provided to one unit water tank WSU may flow through the waterway WP and may be provided to other unit water tanks WSU directly or indirectly connected thereto through the waterway WP, and it is not desired to individually provide the water to each of the unit water tanks WSU. Accordingly, the convenience and efficiency in supplying water to the unit water tank WSU may be improved. Even though FIG. 4 shows the waterway WP connect the eight unit water tanks WSU or the sixteen water tanks WSU, the disclosure is not limited thereto, and the waterway WP may connect a different number of the unit water tanks WSU.

FIGS. 6 and 7 are cross-sectional views taken along line I-I′ of FIG. 1.

Referring to FIGS. 6 and 7, the display panel reliability test device TD (refer to FIG. 1) may further include a first supporter SP1. The first supporter SP1 may be disposed on the supporter SP. The test-purpose display panel TDP (refer to FIG. 10) may be placed on the first supporter SP1. The first supporter SP1 may be provided in plural or may be disposed to surround the water tank WS to increase its support force. The first supporter SP1 may include an insulation material and may prevent the heat generate by the heating plate HP from being transferred directly to the test-purpose display panel TDP (refer to FIG. 10) to improve the accuracy of the test process. Due to the first supporter SP1, a distance from the test-purpose display panel TDP (refer to FIG. 10) to the water contained in the water tank WS may increase, and thus, when the display panel reliability test device is shaken by an external force applied thereto, the water contained in the water tank WS may be prevented from getting onto the test-purpose display panel TDP (refer to FIG. 10). Accordingly, a stability of the test process may be improved.

The display panel reliability test device TD (refer to FIG. 1) may further include a second supporter SP2. The second supporter SP2 may be disposed on the supporter SP. The first supporter SP1 may be disposed between the second supporter SP2 and the water tank WS. The second supporter SP2 may have a height greater than a height of the first supporter SP1. The second supporter SP2 may include an insulation material and may prevent the heat generated by the heating plate HP from being transferred directly to the test-purpose display panel TDP (refer to FIG. 10) to improve the accuracy of the test process. The second supporter SP2 may be provided in plural or may be disposed to surround the water tank WS. When the second supporter SP2 is disposed to surround the water tank WS, the second supporter SP2 may have substantially the same shape as that of the test-purpose display panel TDP (refer to FIG. 10) in the plan view. The second supporter SP2 may prevent the test-purpose display panel TDP (refer to FIG. 10) from moving in the first direction DR1 or a direction opposite to the first direction DR1, and thus, the stability of the test process may be improved.

As shown in FIG. 7, a fixing groove FH may be defined in the supporter SP. The fixing groove FH may be a space defined by recessing a portion of an upper surface of the supporter SP. The fixing groove FH may be defined to surround the water tank WS in the plan view. The fixing groove FH may accommodate a portion of the packing cover PK. When the portion of the packing cover PK is accommodated in the fixing groove FH, the support force may increase. As a result, even though the external force is applied to the display panel reliability test device TD (refer to FIG. 1) or the display panel reliability test device TD (refer to FIG. 1) is tilted, the packing cover PK may not be separated from the jig JG, and thus, the stability of the test process may be improved.

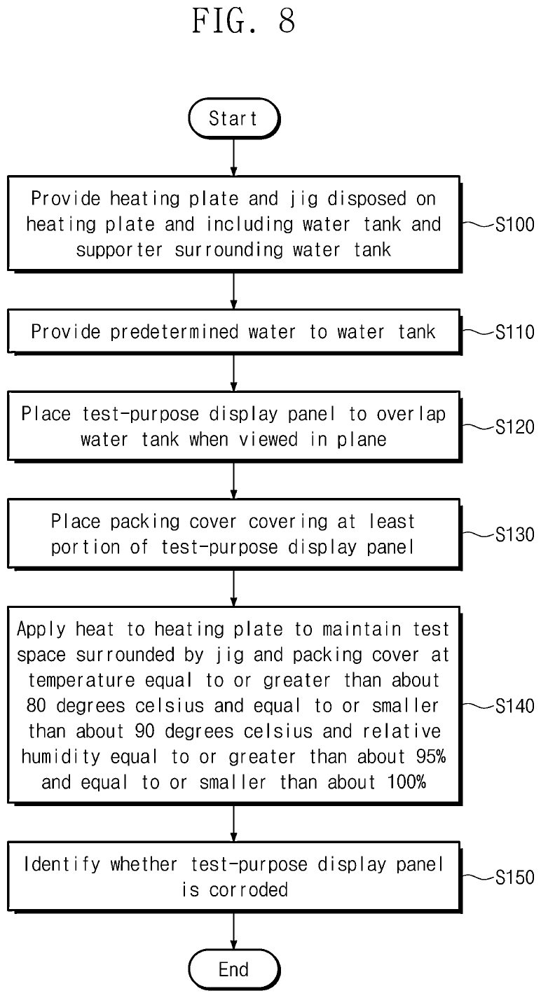

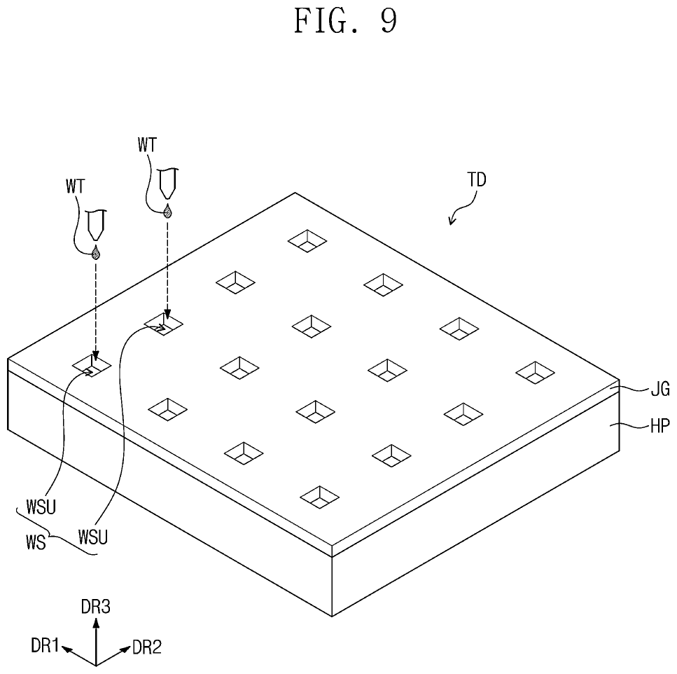

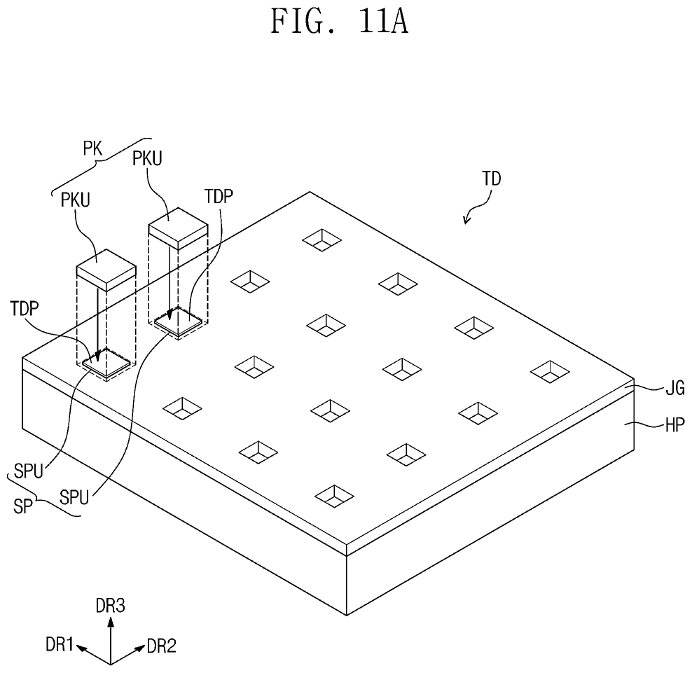

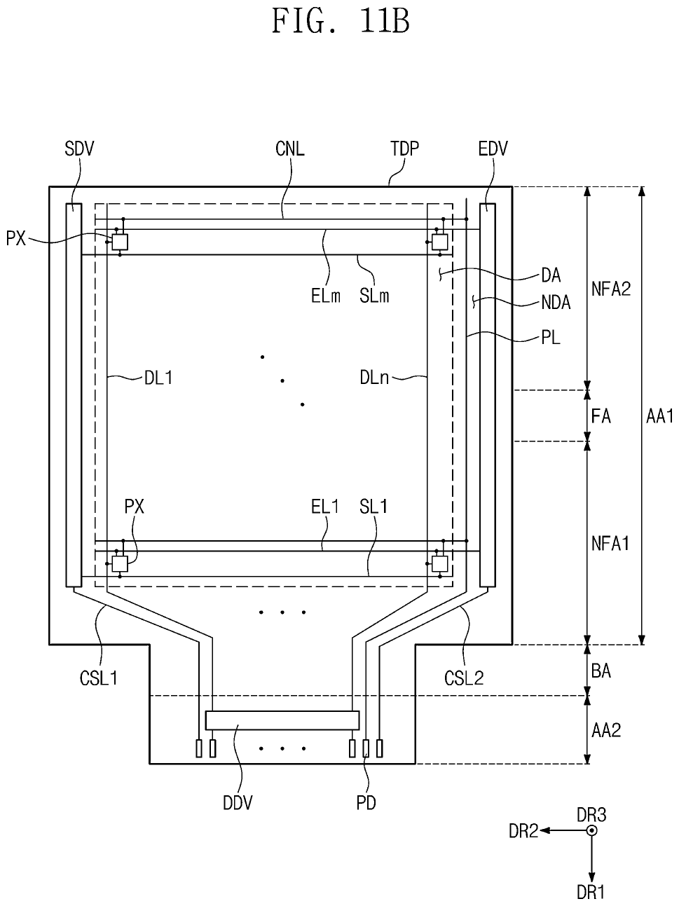

FIG. 8 is a flowchart illustrating an embodiment of a method of testing the reliability of the display panel according to the disclosure. FIG. 9 is a perspective view illustrating an embodiment of a process of the testing method of the reliability of the display panel according to the disclosure. FIG. 10 is a perspective view illustrating an embodiment of a process of the testing method of the reliability of the display panel according to the disclosure. FIG. 11A is a perspective view illustrating an embodiment of a process of the testing method of the reliability of the display panel according to the disclosure.

FIG. 9 shows a second operation (S110) providing a predetermined water WT to the water tank WS. FIG. 10 shows a third operation (S120) placing the test-purpose display panel TDP that overlaps the water tank WS in the plan view. FIG. 11A shows a fourth operation (S130) placing the packing cover PK that covers at least a portion of the test-purpose display panel TDP. Details of the components described with reference to FIGS. 1 to 7 will be omitted. In this description, “a predetermined water” means water by predetermined amount.

Referring to FIG. 8, the display panel reliability test method may include a first operation (S100) providing the heating plate and the jig disposed on the heating plate and including the water tank and the supporter surrounding the water tank, the second operation (S110) providing the predetermined water to the water tank, the third operation (S120) placing the test-purpose display panel to overlap the water tank in the plan view, the fourth operation (S130) placing the packing cover to cover at least the portion of the test-purpose display panel, a fifth operation (S140) heating the heating plate to maintain the test space surrounded by the jig and the packing cover at the temperature equal to or greater than about 80 degrees Celsius and equal to or smaller than about 90 degrees Celsius and the relative humidity equal to or greater than about 95% and equal to or smaller than about 100%, and a sixth operation (S150) identifying whether the test-purpose display panel is corroded.

Referring to FIGS. 8 and 9, the heating plate HP may be directly in contact with the jig JG in the first operation (S100). That is, an upper surface of the heating plate HP may be directly in contact with a lower surface of the jig JG. Different from the jig JG shown in FIG. 9, the jig JG may further include the waterway WP (refer to FIG. 5) connecting at least some of the unit water tanks WSU to each other.

In the second operation (S110), a portion of the water tank WS may be filled with the predetermined water WT provided to the water tank WS. The predetermined water WT provided to the water tank WS may have a volume that keeps the relative humidity of the test space TS (refer to FIG. 6) within a range from about 95% or more to about 100% or less when heated. The second operation (S110) may include a second-first operation that provides the predetermined water WT to each of the unit water tanks WSU. The second-first operation may be a process that provides the predetermined water WT to the unit water tank WSU that is not connected to the waterway WP (refer to FIG. 5) when there is no waterway WP (refer to FIG. 5) connecting the unit water tanks WSU to each other or the waterway WP (refer to FIG. 5) connects only some of the unit water tanks WSU. Different from the case where all the unit water tanks WSU are connected to each other through the waterway WP (refer to FIG. 5) to be filled with the predetermined water WT by providing the predetermined water WT to only one unit water tank WSU, the second-first operation may have advantages of individually adjusting an amount of the predetermined water WT provided to each unit water tank WSU.

Referring to FIGS. 8 and 10, the test-purpose display panel TDP may be placed to overlap the water tank WS in the plan view in the third operation (S120). The test-purpose display panel TDP may be disposed on the supporter SP. The test-purpose display panel TDP may be disposed directly on the supporter SP. The test-purpose display panel TDP may not be in contact directly with the predetermined water WT (refer to FIG. 9) provided to the water tank WS. The test-purpose display panel TDP may be provided in plural. The water tank WS may include the plural unit water tanks WSU. The supporter SP may include the plural unit supporters SPU. The third operation (S120) may include a third-first operation that places the plural test-purpose display panels TDP to respectively overlap the unit water tanks WSU in the plan view. One test-purpose display panel TDP among the test-purpose display panels TDP may be disposed on a corresponding unit supporter SPU among the unit supporters SPU. The test-purpose display panel TDP may be disposed directly on the unit supporter SPU. The test-purpose display panel TDP may be placed on the first supporter SP1 (refer to FIG. 6) disposed on the supporter SP. The test-purpose display panel TDP may be disposed directly on the first supporter SP1 (refer to FIG. 6).

Referring to FIGS. 8 and 11A, in the fourth operation (S130), the packing cover PK may cover an entirety of the portion of the test-purpose display panel TDP or, different from the structure shown in FIG. 11A, may cover only a portion of the test-purpose display panel TDP. The packing cover PK may be disposed directly on the supporter SP. The slot-shaped groove may be defined in the side of the packing cover PK. When the packing cover PK covers only the portion of the test-purpose display panel TDP, a remaining portion of the test-purpose display panel TDP may be exposed through the groove defined in the side of the packing cover PK. When the packing cover PK covers only the portion of the test-purpose display panel TDP, the portion of the test-purpose display panel TDP that is covered by the packing cover PK and the remaining portion of the test-purpose display panel TDP that is not covered by the packing cover PK are exposed to different environments, and the degree of corrosion therebetween may be compared with each other. The packing cover PK may include the unit packing covers PKU. The fourth operation (S130) may further include a fourth-first operation placing the unit packing covers PKU to respectively overlap the test-purpose display panels TDP. In an embodiment, the fourth operation (S130) may not include the fourth-first operation, and the packing cover PK-1 (refer to FIG. 3B) covering all the test-purpose display panels TDP may be disposed in the fourth operation (S130). In the fourth-first operation, each of the unit packing covers PKU may cover at least a portion of the test-purpose display panel TDP. The packing cover PK-1 (refer to FIG. 3B) may cover the plural test-purpose display panels TDP.

FIG. 11B is a plan view of the test-purpose display panel shown in FIG. 11A.

Referring to FIG. 11B, the test-purpose display panel TDP may include a scan driver SDV, a data driver DDV, and an emission driver EDV. The test-purpose display panel TDP may include a first area AA1, a second area AA2, and a bending area BA between the first area AA1 and the second area AA2. The bending area BA may extend in the second direction DR2, and the first area AA1, the bending area BA, and the second area AA2 may be arranged in the first direction DR1.

The first area AA1 may include a display area DA and a non-display area NDA around the display area DA. The non-display area NDA may surround the display area DA. The display area DA may be an area in which an image is displayed, and the non-display area NDA may be an area in which the image is not displayed. The second area AA2 and the bending area BA may be areas in which the image is not displayed.

When viewed in the third direction DR3, the first area AA1 may include a first non-folding area NFA1, a second non-folding area NFA2, and a folding area FA between the first non-folding area NFA1 and the second non-folding area NFA2.

The test-purpose display panel TDP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connection lines CNL, and a plurality of pads PD. Each of m and n is a natural number. The pixels PX may be arranged in the display area DA and may be connected to the scan lines SL1 to SLm, the data lines DL1 to DLn, and the emission lines EL1 to ELm.

The scan driver SDV and the emission driver EDV may be disposed in the non-display area NDA. The scan driver SDV and the emission driver EDV may be disposed in the non-display area NDA to be respectively adjacent to opposite sides of the first area AA1, which are opposite to each other in the second direction DR2. The data driver DDV may be disposed in the second area AA2. The data driver DDV may be manufactured in an integrated circuit chip form and may be disposed (e.g., mounted) on the test-purpose display panel TDP in the second area AA2.

The scan lines SL1 to SLm may extend in the second direction DR2 and may be connected to the scan driver SDV. The data lines DL1 to DLn may extend in the first direction DR1 and may be connected to the data driver DDV via the bending area BA. The emission lines EL1 to ELm may extend in a direction parallel to the second direction DR2 and may be connected to the emission driver EDV.

The power line PL may extend in the first direction DR1 and may be disposed in the non-display area NDA. The power line PL may be disposed between the display area DA and the emission driver EDV, however, it should not be limited thereto or thereby. That is, the power line PL may be disposed between the display area DA and the scan driver SDV.

The power line PL may extend to the second area AA2 via the bending area BA. When viewed in the plan view, the power line PL may extend to a lower end of the second area AA2. The power line PL may receive a driving voltage.

The connection lines CNL may extend in the direction parallel to the second direction DR2 and may be arranged in the first direction DR1. The connection lines CNL may be connected to the power line PL and the pixels PX. The driving voltage may be applied to the pixels PX via the power line PL and the connection lines CNL connected to the power line PL.

The first control line CSL1 may be connected to the scan driver SDV and may extend toward the lower end of the second area AA2 via the bending area BA. The second control line CSL2 may be connected to the emission driver EDV and may extend toward the lower end of the second area AA2 via the bending area BA. The data driver DDV may be disposed between the first control line CSL1 and the second control line CSL2.

When viewed in the plan view, the pads PD may be disposed adjacent to the lower end of the second area AA2. The data driver DDV, the power line PL, the first control line CSL1, and the second control line CSL2 may be connected to the pads PD.

The data lines DL1 to DLn may be connected to corresponding pads PD via the data driver DDV. In an embodiment, the data lines DL1 to DLn may be connected to the data driver DDV, and the data driver DDV may be connected to the pads PD corresponding to the data lines DL1 to DLn.

Although not shown in drawing figures, a printed circuit board may be connected to the pads PD, and a timing controller and a voltage generator may be disposed on the printed circuit board. The timing controller may be manufactured in an integrated circuit chip form and may be disposed (e.g., mounted) on the printed circuit board. The timing controller and the voltage generator may be connected to the pads PD via the printed circuit board.

The timing controller may control an operation of the scan driver SDV, the data driver DDV, and the emission driver EDV. The timing controller may generate a scan control signal, a data control signal, and an emission control signal in response to control signals applied thereto from the outside. The voltage generator may generate the driving voltage.

The scan control signal may be applied to the scan driver SDV via the first control line CSL1. The emission control signal may be applied to the emission driver EDV via the second control line CSL2. The data control signal may be applied to the data driver DDV. The timing controller may receive image signals from the outside, may convert a data format of the image signals to a data format appropriate to an interface between the timing controller and the data driver DDV, and may provide the converted image signals to the data driver DDV.

The scan driver SDV may generate a plurality of scan signals in response to the scan control signal. The scan signals may be applied to the pixels PX via the scan lines SL1 to SLm. The scan signals may be sequentially applied to the pixels PX.

The data driver DDV may generate a plurality of data voltages corresponding to the image signals in response to the data control signal. The data voltages may be applied to the pixels PX via the data lines DL1 to DLn. The emission driver EDV may generate a plurality of emission signals in response to the emission control signal. The emission signals may be applied to the pixels PX via the emission lines EL1 to ELm.

The pixels PX may receive the data voltages in response to the scan signals. The pixels PX may emit a light having a luminance corresponding to the data voltages in response to the emission signals, and thus, the image may be displayed. An emission time of the pixels PX may be controlled by the emission signals.

When the test-purpose display panel TDP is exposed to the relatively high temperature and humidity environment, the moisture may easily penetrate into the test-purpose display panel TDP through the bending area BA. When a concentration of the moisture penetrating into the test-purpose display panel TDP through the bending area BA increases and the data lines DL1 to DLn, the scan lines SL1 to SLm, the emission lines EL1 to ELm, the power line PL, the connection lines CNL, the first control line CSL1, or the second control line CSL2 are corroded, the pixels PX may not receive the data voltages even though the scan signals are applied thereto. In addition, since the pixels PX do not receive the data voltages, the pixels PX may not emit lights at the luminance corresponding to the data voltages, and thus, the image may not be displayed. As the display panel reliability test device TD (refer to FIG. 1) provides an environment in which the test-purpose display panel TDP is exposed to the relatively high temperature and humidity environment for a predetermined length of time, the occurrence of corrosion caused by the moisture penetrating into the test-purpose display panel TDP through the bending area BA of the test-purpose display panel TDP may be tested within a short period of time.

Referring to FIG. 8, the test space may be maintained at the temperature equal to or greater than about 80 degrees Celsius and equal to or smaller than about 90 degrees Celsius and the relative humidity equal to or greater than about 95% and equal to or smaller than about 100% for about 300 hours or more in the fifth operation (S140). In a case where the fifth operation (S140) is maintained for less than about 300 hours, the frequency of corrosion occurring on the test-purpose display panel TDP is low, and thus, it is difficult to analyze data.

In the sixth operation (S150), whether the test-purpose display panel TDP is corroded or not may be identified through observation of discoloration with the naked eye, observation of discoloration using a microscope, observation of operation status of the test-purpose display panel TDP, or the like.

Hereinafter, results of evaluating the reliability of the display panel through the display panel reliability test method using the display panel reliability test device according to the disclosure will be described in detail.

The display panel reliability test device to which the display panel reliability test method is applied includes the heating plate, the jig, and thirty unit packing covers, which are shown in FIG. 1. The jig includes thirty unit water tanks and thirty unit supporters. The slot-shaped groove is defined in the side of each of the thirty unit packing covers. Each of the thirty unit water tanks is filled with the water, thirty test-purpose display panels are disposed to respectively overlap the thirty unit water tanks in the plan view, and then each of the unit packing covers is disposed to cover a half of a corresponding test-purpose display panel among the thirty test-purpose display panels. That is, the half of the test-purpose display panel is disposed in the test space, and the other half of the test-purpose display panel is disposed outside the test space through the groove defined in the side of each of the unit packing cover. A gap between the groove defined in the side of the packing cover and the test-purpose display panel is filled with a rubber packing to seal the test space. Then, the heat is applied to the heating plate to maintain the test space at the temperature of about 85 degrees Celsius and the relative humidity of about 100% and the space other than the test space at the temperature of about 85 degrees Celsius and the relative humidity of about 85%, and the time at which corrosion occurs on the test-purpose display panel is analyzed and shown in Table 1 below. Experimental embodiment indicates portions of the thirty test-purpose display panels, which are disposed in the test space, and Comparative example 1 indicates portions of the thirty test-purpose display panels, which are disposed in the space other than the test space. Conditions in which more corrosion occurs on the display panel during the same period of time may be interpreted as improved efficiency because corrosion on the display panel may be confirmed more quickly.

TABLE 1

| | | | | | |
|---|---|---|---|---|---|
| Experimental embodiment | 288 | 312 | 336 | 432 | 456 |
| Corrosion occurrence time | | | | | |
| (h) | | | | | |
| Number of occurrences of | 2 | 1 | 1 | 1 | 1 |
| corrosion in Experimental | | | | | |
| embodiments | | | | | |

| | |
|---|---|
| Comparative example 1 | 1008 |
| Corrosion occurrence time | |
| (h) | |
| Number of occurrences of | 2 |
| corrosion in Comparative | |
| example | |

Referring to Table 1, in the Experimental embodiment, corrosion occurred in two test-purpose display panels out of thirty test-purpose display panels after about 288 hours, and corrosion occurred in a total of six test-purpose display panels out of thirty test-purpose display panels after about 456 hours. In Comparative example 1, corrosion occurred in two test-purpose display panels out of thirty test-purpose display panels after about 1008 hours. Accordingly, corrosion occurred in more test-purpose display panels in a relatively short period of time in Experimental embodiment compared to Comparative example 1, and this is interpreted that the efficiency in the reliability test is improved.

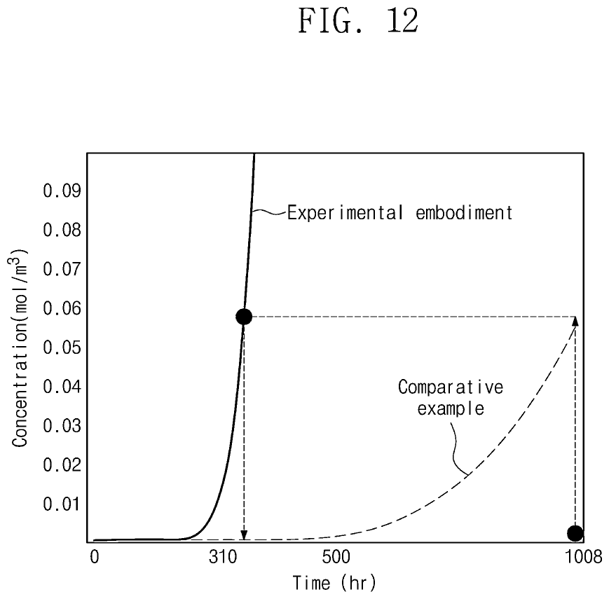

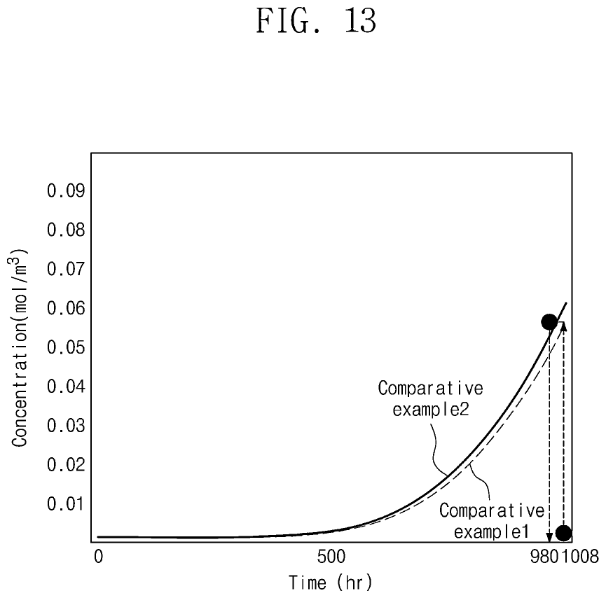

FIG. 12 shows graphs illustrating a moisture concentration as a function of time in the test-purpose display panel of Experimental embodiment and Comparative example 1. FIG. 13 shows graphs illustrating a moisture concentration as a function of time in the test-purpose display panel of Comparative examples 1 and 2. FIGS. 12 and 13 are graphs of data obtained through simulation.

FIG. 12 shows graphs illustrating a moisture concentration as a function of time in each display panel of Experimental embodiment and Comparative example 1. FIG. 13 shows graphs illustrating a moisture concentration as a function of time in each display panel of Comparative examples 1 and 2. The graph of Experimental embodiment increases faster than the graph of Comparative example 1, and this may be interpreted that the moisture concentration of the display panel of Experimental embodiment increases faster than the moisture concentration of the display panel of Comparative example 1. The moisture concentration at which corrosion begins to occur in the display panel is about 0.06 mole per cubic meter (mol/m³), the time it takes for the moisture concentration of the display panel in Comparative example 1 to reach about 0.06 mol/m³ is about 1000 hours (hr), and the time it takes for the moisture concentration of the display panel of Experimental embodiment to reach about 0.06 mol/m³ is about 310 hr.

Comparative Example 2 shows the moisture concentration of the display panel as a function of time obtained when the display panel is placed within the test space and is exposed to an environment with the temperature of about 85 degrees Celsius and the relative humidity of about 90%. Since Comparative example 2 has a higher relative humidity compared to Comparative example 1, it takes less time for the moisture concentration of the display panel to reach about 0.06 mol/m³ compared to Comparative example 1. However, since the relative humidity of the display panel of Comparative example 2 is not sufficiently high, it still takes about 980 hr for the moisture concentration of the display panel to reach about 0.06 mol/m³, and thus, the moisture concentration of the display panel increases significantly more slowly than Experimental embodiment. This is because, in the case of Experimental embodiment, the relative humidity is relatively high and the water vapor condenses into liquid inside or outside the display panel, allowing the display panel to contact more water molecules.

The display panel reliability test device according to the disclosure may include the heating plate, the jig disposed on the heating plate and including the water tank and the supporter surrounding the water tank, and the packing cover disposed on the jig and overlapping the water tank in the plan view. The test space surrounded by the jig and the packing cover and accommodating the test-purpose display panel therein may be maintained at the temperature equal to or greater than about 80 degrees Celsius and equal to or smaller than about 90 degrees Celsius and the relative humidity equal to or greater than about 95% and equal to or smaller than about 100% for about 300 hr or more. As a result, the water may be condensed on the display panel placed in the test space, and the display panel may be more quickly corroded, thereby improving the efficiency of the reliability test method. In addition, the configuration of the display panel reliability test device is simple and inexpensive compared to a conventional test device used in a conventional display panel reliability test method, and thus, the convenience and economic efficiency of the display panel reliability test method may be improved.

Although the embodiments of the disclosure have been described, it is understood that the disclosure should not be limited to these embodiments but various changes and modifications may be made by one ordinary skilled in the art within the spirit and scope of the disclosure as hereinafter claimed. Therefore, the disclosed subject matter should not be limited to any single embodiment described herein, and the scope of the inventive concept shall be determined according to the attached claims.

What is claimed is:

1. A device of testing a reliability of a display panel, the device comprising:
a heating plate;
a jig disposed on the heating plate and comprising a water tank and a supporter surrounding the water tank; and
a packing cover disposed on the jig and overlapping the water tank in a plan view,
wherein a test space defined as a space surrounded by the jig and the packing cover and accommodating a test-purpose display panel therein is maintained at a temperature equal to or greater than about 80 degrees Celsius and equal to or smaller than about 90 degrees Celsius and a relative humidity equal to or greater than about 95% and equal to or smaller than about 100% for about 300 hours or more.

2. The device of claim 1, wherein the water tank comprises a plurality of unit water tanks, the supporter comprises a plurality of unit supporters respectively surrounding the plurality of unit water tanks, and the packing cover comprises a plurality of unit packing covers respectively overlapping the plurality of unit water tanks in the plan view.

3. The device of claim 2, wherein the jig further comprises a waterway connecting at least some of the plurality of unit water tanks to each other.

4. The device of claim 1, wherein the water tank comprises a plurality of water tanks, and the packing cover overlaps the plurality of unit water tanks in the plan view.

5. The device of claim 1, wherein the jig is disposed directly on the heating plate.

6. The device of claim 1, wherein the packing cover is disposed directly on the jig.

7. The device of claim 1, wherein the heating plate comprises a thermally conductive material.

8. The device of claim 7, wherein the thermally conductive material comprises at least one of Fe, Cu, Ag, Au, Al, and W.

9. The device of claim 1, wherein the supporter comprises a thermally conductive material.

10. The device of claim 9, wherein the thermally conductive material comprises at least one of Fe, Cu, Ag, Au, Al, and W.

11. The device of claim 1, further comprising a first supporter disposed on the supporter, wherein the test-purpose display panel is placed on the first supporter.

12. The device of claim 11, further comprising a second supporter disposed on the supporter and preventing the test-purpose display panel from moving in a first direction or a direction opposite to the first direction.

13. The device of claim 1, wherein a fixing groove is defined in the supporter, and a portion of the packing cover is disposed in the fixing groove.

14. The device of claim 13, wherein the fixing groove surrounds the water tank in the plan view.

15. The device of claim 1, wherein the packing cover has a quadrangular shape in the plan view.

16. A method of testing a reliability of a display panel, the method comprising:
providing a heating plate and a jig disposed on the heating plate and comprising a water tank and a supporter surrounding the water tank;
providing a predetermined water to the water tank;
placing a test-purpose display panel to overlap the water tank in a plan view;
placing a packing cover to cover at least a portion of the test-purpose display panel;
applying a heat to the heating plate to maintain a test space defined as a space surrounded by the jig and the packing cover at a temperature equal to or greater than about 80 degrees Celsius and equal to or smaller than about 90 degrees Celsius and a relative humidity equal to or greater than about 95% and equal to or smaller than about 100%; and
identifying whether the test-purpose display panel is corroded.

17. The method of claim 16, wherein the water tank comprises a plurality of unit water tanks, the supporter comprises a plurality of unit supporters respectively surrounding the plurality of unit water tanks, the packing cover comprises a plurality of unit packing covers respectively overlapping the plurality of unit water tanks in the plan view, the providing the predetermined water comprises providing water to each of the plurality of unit water tanks, the placing the test-purpose display panel comprises placing a plurality of test-purpose display panels to respectively overlap the plurality of unit water tanks, and the placing the packing cover comprises placing the unit packing covers to respectively cover the plurality of test-purpose display panels.

18. The method of claim 17, wherein the jig further comprises a waterway connecting at least some of the plurality of unit water tanks to each other.

19. The method of claim 16, wherein the placing the test-purpose display panel is performed to place the test-purpose display panel on a first supporter disposed on the supporter, and the test-purpose display panel placed on the first supporter overlaps the water tank in the plan view.

20. The method of claim 16, wherein the applying the heat to the heating plate is performed to maintain the test space at the temperature equal to or greater than about 80 degrees Celsius and equal to or smaller than about 90 degrees Celsius and the relative humidity equal to or greater than about 95% and equal to or smaller than about 100% for about 300 hours or more.
